(19) United States
(12) Patent Application Publication
(10) Pub. No.: US 2008/0286899 A1
(43) Pub. Date: Nov. 20, 2008

(54) METHOD FOR MANUFACTURING SEMICONDUCTOR DEVICE AND METHOD FOR MANUFACTURING SYSTEM-IN-PACKAGE USING THE SAME

(76) Inventor: Oh-Jin Jung, Yongin-si (KR)

Correspondence Address: SHERR & VAUGHN, PLLC, 620 HERNDON PARKWAY, SUITE 200, HERNDON, VA, 20170, US

(21) Appl. No.: 12/120,267

(22) Filed: May 14, 2008

(30) Foreign Application Priority Data
May 18, 2007 (KR) 10-2007-0048410

(51) Int. Cl. H01L 21/60; H01L 21/44

(52) U.S. Cl. 438/107; 438/612; 257/E21.509; 257/E21.476

(57) ABSTRACT

A method for manufacturing a semiconductor device and a method for manufacturing a system-in-package using the same, which are capable of enhancing reliability and the step coverage for a trench having a high aspect ratio. The semiconductor manufacturing method includes forming a first insulating film over a substrate; and then forming first and second metal patterns over the first insulating film; and then forming a second insulating film over the first insulating film including the first and second metal patterns; and then forming a trench extending through the first and second insulating films and into the substrate thereby exposing the substrate; and then sequentially forming first and second oxide films over the second insulating film and in the trench; and then forming a via hole exposing the first metal pattern; and then sequentially forming first and second barrier metal films over a resultant surface of the substrate including the second oxide film; and then forming a copper layer over the second barrier metal film and in the trench and the via hole; and then planarizing the copper layer exposing a portion of the second barrier metal film; and then forming a copper pad by recessing predetermined portions of the second barrier metal film, the first barrier metal film, the second oxide film and the first oxide film exposing the second insulating film at opposite sides of the copper pad.

This application claims priority under 35 U.S.C. 119 to Korean Patent Application No. 10-2007-0048410 (filed on May 18, 2008) which is hereby incorporated by reference in its entirety.

### BACKGROUND

Presently, there is an increased demand for portable electronic devices, particularly electronic appliances. Moreover, there is also an increased demand for highly integrated semiconductor devices for application in such electronic appliances. In an attempt to manufacture such high integration, the use of a shallow trench isolation (STI) type isolation film as an isolation film is being increased. In an isolation method using STI, a trench is formed, and an oxide film may be filled in the trench. This isolation method can eliminate a problem of bird's beak, as compared to a local oxidation of silicon (LOCOS) method.

Moreover, when attempting to manufacture a highly integrated semiconductor device, an increase in aspect ratio may occur because the width of a trench, in which an isolation film may be filled, is reduced under the condition in which the depth of the trench is constant. Therefore, it may be required to fill a silicon oxide film in the trench without forming a defect such as a void or a seam.

Various proposals have been made to provide a method capable of forming an oxide film exhibiting superior gap filling characteristics such that the oxide film can be filled in a trench having a high aspect ratio. One proposal is an oxide film forming method using tetra ethyl ortho silicate (TEOS), undoped silicate glass (USG), high density plasma (HDP), or chemical vapor deposition (CVD).

Use of such an oxide film forming method requiring TEOS, USG, HDP, or CVD, however, may result in a limitation on gap filling characteristics when applied to fill an oxide film in a trench having an aspect ratio of about 5 without forming any defect. Accordingly, such oxide film forming method exhibits inferior step coverage characteristics. In turn, there may be problems of thermal expansion occurring in a subsequent process and cracks formed in a subsequent sawing process.

### SUMMARY

Embodiments relate to a semiconductor device, and more particularly, to a method for manufacturing a semiconductor device and a method for manufacturing a system-in-package (SIP) using the same, which can achieve an enhancement in the step coverage for a trench having a high aspect ratio and an enhancement in reliability.

Embodiments relate to a method for manufacturing a semiconductor device that can include at least one of the following steps: forming a first insulating film over a substrate; forming first and second metal patterns on the first insulating film; forming a second insulating film to cover the first insulating film and the first and second metal patterns; forming a trench through the first and second insulating films such that the substrate is exposed through the trench; sequentially forming first and second oxide films over the second insulating film and in the trench; forming a via hole such that the first metal pattern is exposed through the via hole; sequentially forming first and second barrier metal films, to cover a resultant surface of the substrate; forming a copper layer over the second barrier metal film such that the copper layer fills the trench and the via hole; planarizing the copper layer such that the second barrier metal film is partially exposed; and recessing a resultant structure of the substrate at opposite sides of a region including the copper layer and the first and second barrier metal films surrounding the copper layer, such that the second insulating film is exposed, to form a copper pad.

### DRAWINGS

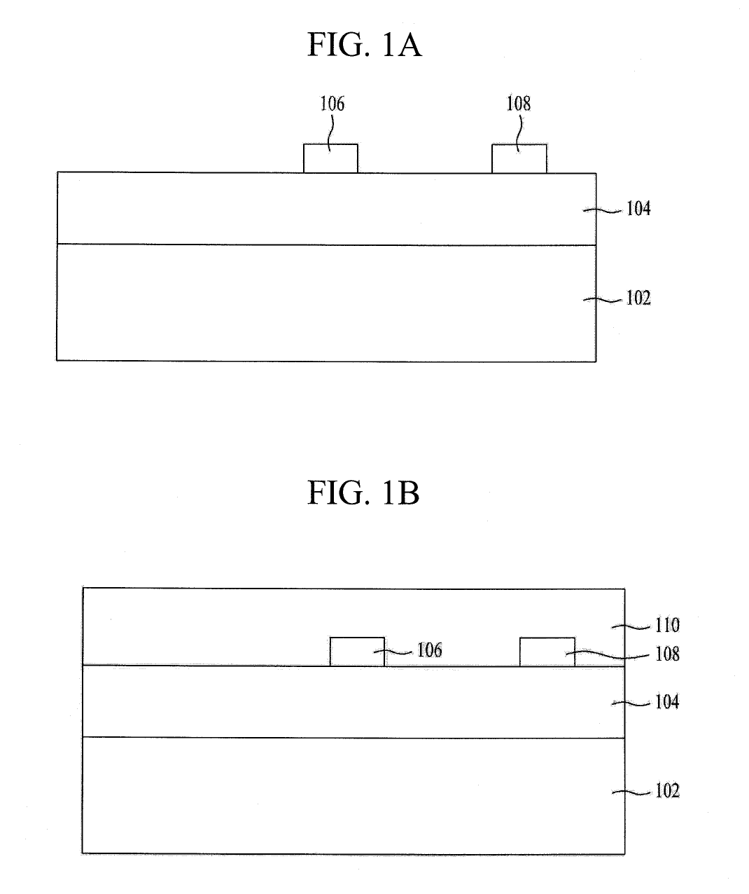

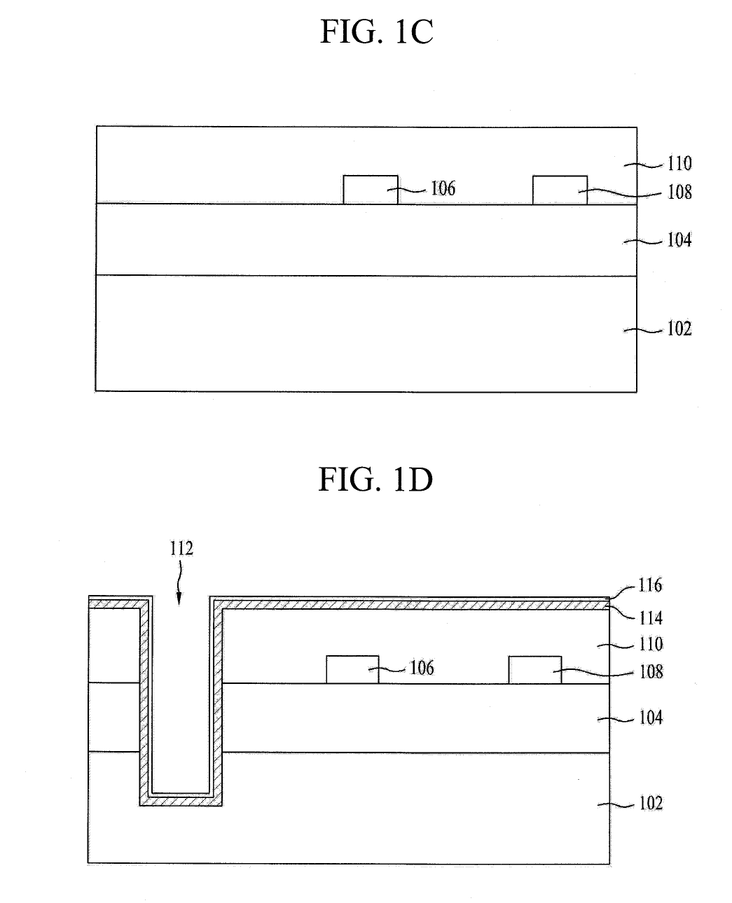

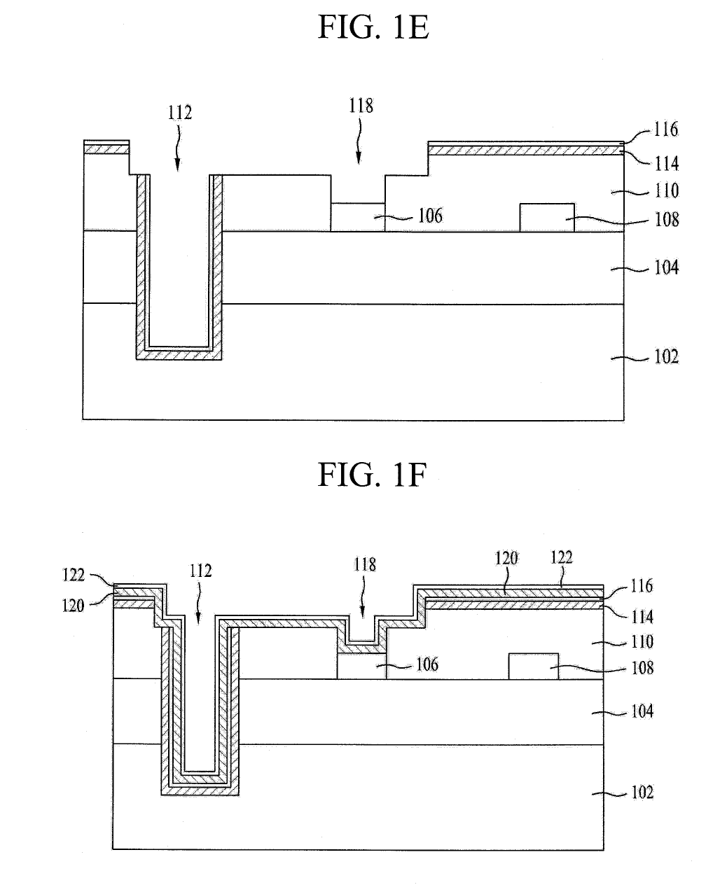

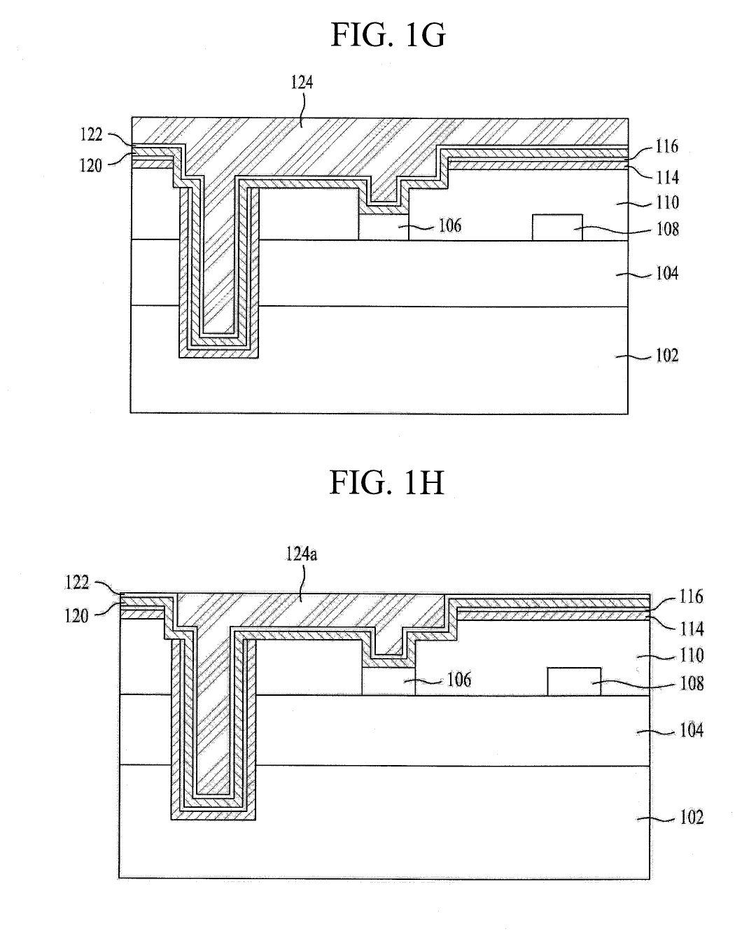

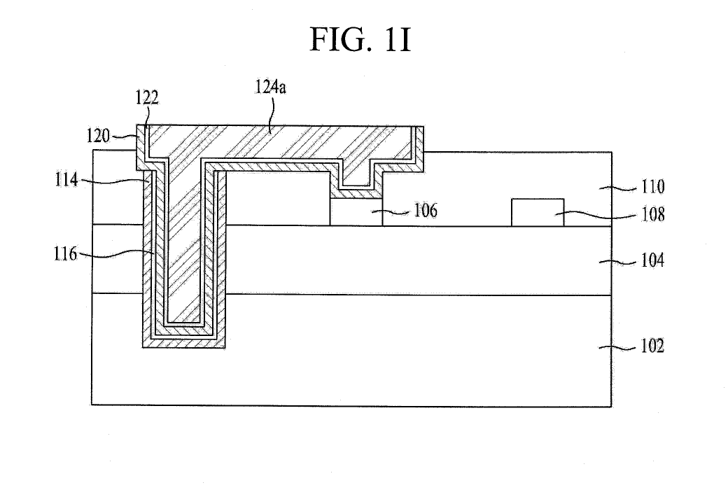

Example FIGS. 1A to 1I illustrate a method for manufacturing a semiconductor device, in accordance with embodiments.

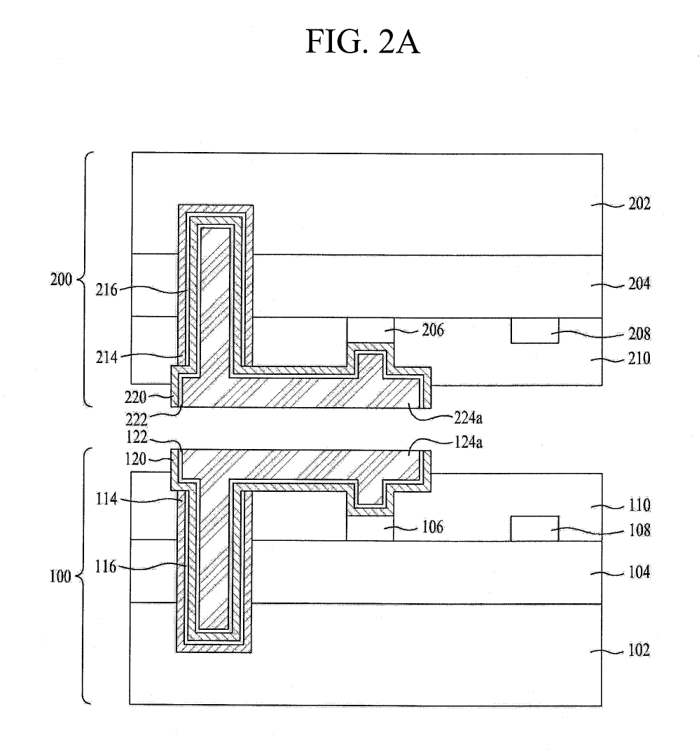

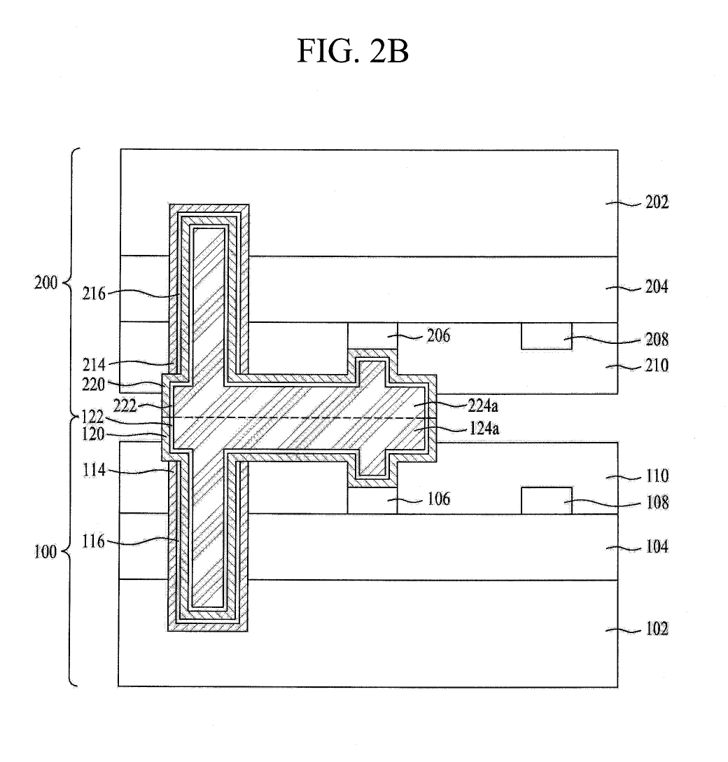

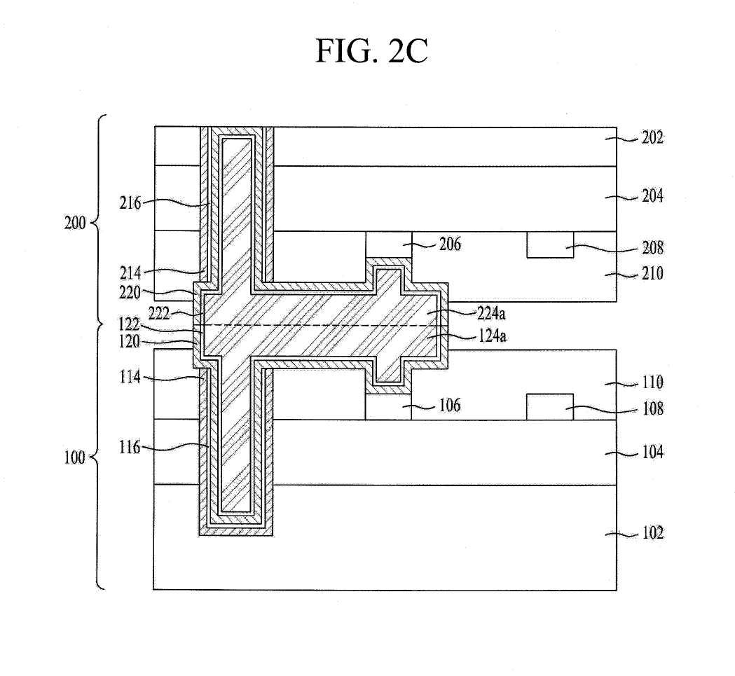

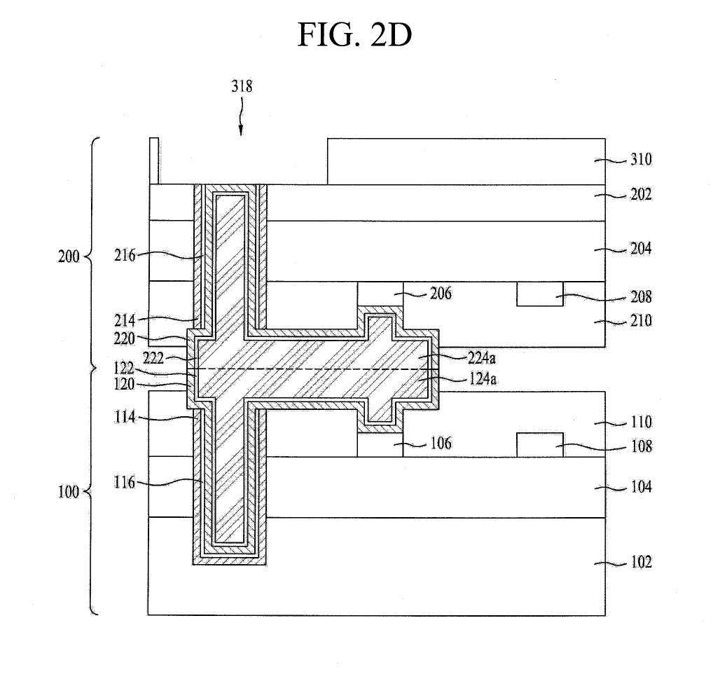

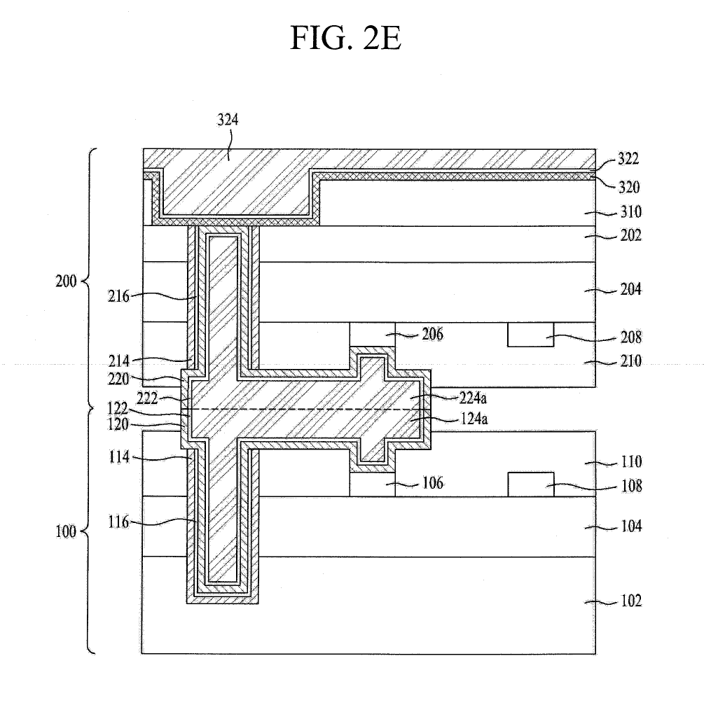

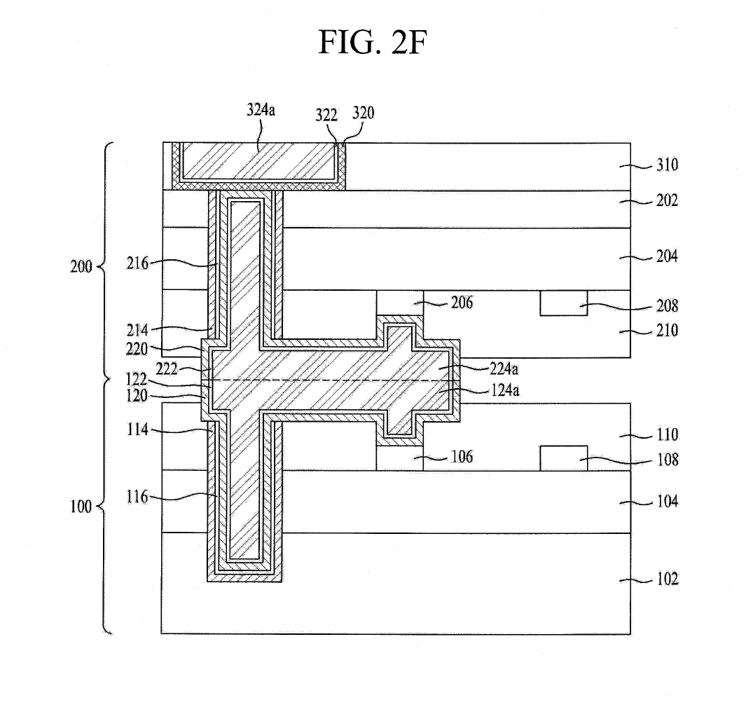

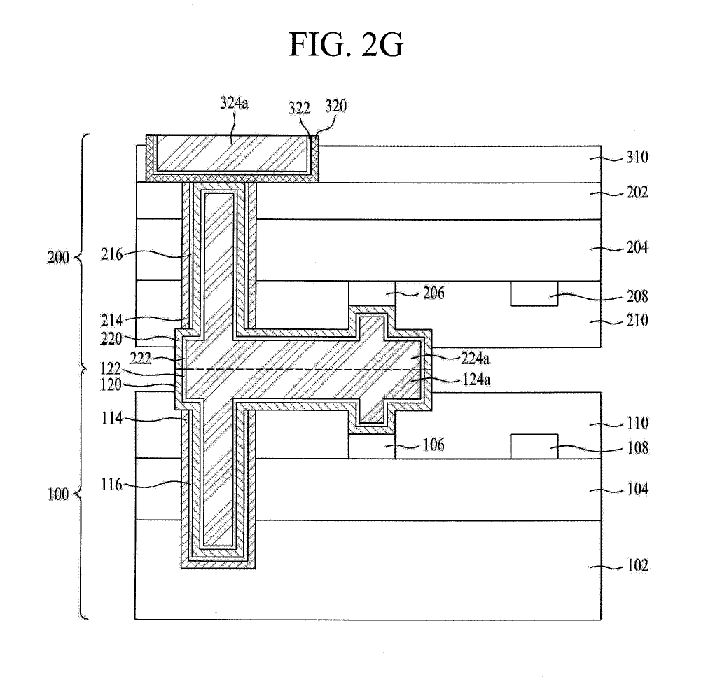

Example FIGS. 2A to 2G illustrate a method for manufacturing a system-in-package in accordance with embodiments.

### DESCRIPTION

As illustrated in example FIGS. 1A to 1I, a semiconductor device manufacturing method in accordance with embodiments can include forming first insulating film 104 on and/or over substrate 102; forming first metal pattern 106 and second metal pattern 108 on and/or over first insulating film 104; forming second insulating film 110 on and/or over first insulating film 104, first metal pattern and second metal pattern 108; forming trench 112 through the first insulating film 104 and second insulating film 110 exposing a portion of substrate 102; sequentially forming first oxide film 114 and second oxide film 116 on and/or over second insulating film 110 and in trench 112; forming a via hole 118 exposing first metal pattern 106; sequentially forming first barrier metal film 120 and second barrier metal film 122 on and/or over a resultant surface of substrate 102; forming copper layer 124 on and/or over second barrier metal film 122 and in trench 122 and via hole 118; planarizing copper layer 124 exposing a portion of second barrier metal film 122; and recessing the resultant structure of substrate 102 at opposite sides of a region including the copper layer 124 and first barrier metal film 120 and second barrier metal 122 surrounding copper layer 124 to thereby expose second insulating film 110.

As illustrated in example FIG. 1A, initially, first insulating film 104 can be formed on and/or over substrate 102 such as a silicon substrate. The formation of first insulating film 104 can be achieved using a deposition method such as plasma enhanced chemical vapor deposition (PECVD). First insulating film 104 can be composed of an inorganic or organic insulating material such as silicon oxide (SiOn) or silicon nitride (SiNx).

First and second metal patterns 106 and 108 can then be formed on and/or over first insulating film 104. The formation of first and second metal patterns 106 and 108 can be achieved by depositing a metal layer first insulating film 104 using a deposition method such as sputtering, and patterning the deposited metal layer using a photo and etch process using a mask. The metal layer can have a single or multi-layered structure, and be composed of a metal material such as Mo, Ti, Cu, AlNd, Al, Cr, an Mo alloy, a Cu alloy, or an Al alloy.

As illustrated in example FIG. 1B, second insulating film 110 can then be formed on and/or over the resultant surface of substrate 102 including first and second metal patterns 106 and 108 and first insulating film 104. The formation of second insulating film 110 can be achieved using a deposition method such as PECVD. Second insulating film 110 can be composed of an inorganic or organic material such as silicon oxide (SiOn) or silicon nitride (SiNx).

As illustrated in example FIG. 1C, the resultant structure can then be etched to form trench 112 extending through first and second insulating film 104 and 110 and a certain depth into substrate 102, thereby exposing substrate 102. The formation of trench 112 can be achieved using a photo and etch process using a mask.

As illustrated in example FIG. 1D, first oxide film 114 can then be formed on and/or over the resultant surface of second insulating film 110 including trench 112. The formation of first oxide film 114 can be achieved using a deposition method such as PECVD. Second oxide film 116 can then be formed on and/or over first oxide film 114 using an atomic layer deposition (ALD) method. Each one of first and second oxide films 114 and 116 can be formed using a material selected from TEOS, SiN, and SiC, in a process atmosphere having a pressure between 100 mTorr to 30 Torr, at a temperature of between 100 to 700° C. and a power of between 200 to 2,000 W. First oxide film 114 can have a deposition thickness of 1,000 to 3,000 Å while second oxide film 116 can have a deposition thickness of 10 to 20 Å.

As illustrated in example FIG. 1E, via hole 118 can then be formed exposing first metal pattern 106. The formation of via hole 118 can be achieved by etching first and second oxide films 114 and 116 and second insulating film 110 to expose first metal pattern 106 using a photo and etch process using a mask.

As illustrated in example FIG. 1F, first barrier metal film 120 can then be formed on and/or over the resultant surface of second oxide film 116 including trench 112 and via hole 118. The formation of first barrier metal film 120 can be achieved using a deposition method such as sputtering. Second barrier metal film 122 can then be then formed on and/or over first barrier metal film 120 using an ALD method. Each one of first and second barrier metal films 120 and 122 can be formed using a material selected from Ti, TiN, Ta, TaN, TiSiN and any combination thereof in a process atmosphere having a pressure of between 100 mTorr to 50 Torr, at a temperature of between 200 to 800° C. and a power of between 200 to 2,000 W. First barrier metal film 120 can have a deposition thickness of between 500 to 2,000 Å and second barrier metal film 122 can have a deposition thickness of between 10 to 20 Å.

Since first oxide film 114 and second oxide film 116 and first barrier metal film 120 and second barrier metal film 122 are deposited through a deposition process using a PECVD method or a sputtering method and a re-deposition process using an ALD method, as described above, to fill trench 112 having a high aspect ratio, step coverage and reliability of first oxide film 114, second oxide film 116, first barrier metal film 120 and second barrier metal film 122 can be enhanced.

As illustrated in example FIG. 1G, metal layer such as copper layer 124 can then be formed on and/or over second barrier metal film 122 and filling in trench 112. The formation of copper layer 124 can be achieved using an electroplating method.

As illustrated in example FIG. 1H, copper layer 124 can then be etched using a chemical mechanical polishing (CMP) method or an etchback method over the entire surface thereof exposing second barrier metal film 122. A predetermined portion of second barrier metal film 122 remains after the etching of the copper layer 124, together with respective portions of first barrier metal film 120, second oxide film 116, and first oxide film 114 arranged beneath the predetermined portion of second barrier metal film 122.

As illustrated in example FIG. 1I, the predetermined portions of the remaining second barrier metal film 122, first barrier metal film 120, second oxide film 116, and first oxide film 114 can be recessed exposing second insulating film 110 at opposite sides of a region including the remaining copper layer 124, namely, copper layer 124a, and first and second barrier metal films 120 and 122 surrounding copper layer 124a.

Example FIGS. 2A to 2G illustrate a method for manufacturing a system-in-package in accordance with embodiments.

As illustrated in example FIG. 2A, initially first and second semiconductor devices 100 and 200 are first prepared. Each one of first and second semiconductor devices 100 and 200 can have the same structure as the semiconductor device manufactured in accordance with the method described above. Accordingly, the description of first and second semiconductor devices 100 and 200 is substituted with the description given in conjunction illustrated in example FIGS. 1A to 1I.

As illustrated in example FIG. 2B, copper layer 124a of first semiconductor device 100 and first and second barrier metal films 120 and 122 surrounding copper layer 124 can be bonded to copper layer 224a of second semiconductor device 200 and first and second barrier metal films 220 and 222 surrounding copper layer 224a, respectively. The bonding of first and second semiconductor devices 100 and 200 can be achieved using a thermal diffusion method.

As illustrated in example FIG. 2C, second substrate 202 of second semiconductor device 200 can then be etched over the entire surface thereof opposite first semiconductor device 100 to expose predetermined portions of second semiconductor device 200, namely, first oxide film 214, second oxide film 216 and first barrier metal film 220. Such etching may be performed using a CMP or etchback method.

As illustrated in example FIG. 2D, third insulating film 310 can then be formed on and/or over the exposed surfaces of substrate 202, first oxide film 214, second oxide film 216, and first barrier metal film 220. The formation of third insulating film 310 can be achieved using a deposition method such as PECVD. Third insulating film 310 can be composed of an inorganic or organic insulating material such as silicon oxide (SiOn) or silicon nitride (SiNx). Pad hole 318 can then be formed through third insulating film 310 exposing the predetermined portions of substrate 202, first oxide film 214, second oxide film 216 and first barrier metal film 220. The formation of pad hole 218 can be achieved using a photolithography process.

As illustrated in example FIG. 2E, third barrier metal film 320 can then be formed on and/or over the resultant surface of third insulating film 310 including pad hole 318. The formation of third barrier metal film 320 can be achieved using a deposition method such as sputtering. Fourth barrier metal film 322 can then be formed on and/or over third barrier metal film 320 using an ALD method. Each one of third and fourth barrier metal films 320 and 322 can be formed using a material selected from Ti, TiN, Ta, TaN, TiSiN, and any combination thereof in a process atmosphere having a pressure of between 100 mTorr to 50 Torr, at a temperature of between 200 to 800° C. and a power of between 200 to 2,000 W. Third barrier metal film 320 can have a deposition thickness of 500 to 2,000 Å and fourth barrier metal film 322 can have a deposition thickness of 10 to 20 Å. Copper layer 324 can then be formed over fourth barrier metal film 322 and in pad hole 318. The formation of copper layer 324 can be achieved using an electro-plating method.

As illustrated in example FIG. 2F, copper layer 324 can then be etched over the entire surface thereof exposing third insulating film 310 using a chemical mechanical polishing (CMP) method or an etchback method. Third insulating film 310 can then be recessed such that copper layer 324a and first and second barrier metal films 320 and 322 surrounding copper layer 324a protrude therefrom to form a copper pad.

As illustrated in example FIGS. 2A to 2F, it can be seen that the system-in-package manufacturing method in accordance with embodiments can include: the procedures for forming first and second semiconductor devices 100 and 200; bonding first and second semiconductor devices 100 and 200; planarizing substrate 202 of second semiconductor device 200 exposing first barrier metal film 216; forming insulating film 310 on and/or over the planarized surface of substrate 202; forming pad hole 318 exposing first barrier metal film 216 of second semiconductor device 200; forming third and fourth barrier metal films 320 and 322 in pad hole 318; forming copper layer 324 in pad hole 318 and on and/or over third and fourth barrier metal films 320 and 322; and recessing the resultant surface of substrate 202 until third insulating film 310 is exposed such that copper layer 324 and third and fourth barrier metal films 320 and 322 surrounding copper layer 324 protrude therefrom.

Such a system-in-package formed in accordance with embodiments can result in a highly integrated semiconductor having semiconductor size yet greatly-increased storage capacity by connecting two semiconductor devices by a copper layer formed in a trench.

As apparent from the above description, in the semiconductor device manufacturing method in accordance with embodiments, oxide films and barrier metal films are deposited through a deposition process using a PECVD method or a sputtering method and a re-deposition process using an ALD method, to fill a trench having a high aspect ratio. Accordingly, step coverage and reliability of the oxide films and barrier metal films formed in the trench can be enhanced.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device comprising:
forming a first insulating film over a substrate; and then
forming first and second metal patterns over the first insulating film; and then
forming a second insulating film over the first insulating film including the first and second metal patterns; and then
forming a trench extending through the first and second insulating films and into the substrate thereby exposing the substrate; and then
sequentially forming first and second oxide films over the second insulating film and in the trench; and then
forming a via hole exposing the first metal pattern; and then
sequentially forming first and second barrier metal films over a resultant surface of the substrate including the second oxide film; and then
forming a copper layer over the second barrier metal film and in the trench and the via hole; and then
planarizing the copper layer exposing a portion of the second barrier metal film; and then
forming a copper pad by recessing predetermined portions of the second barrier metal film, the first barrier metal film, the second oxide film and the first oxide film exposing the second insulating film at opposite sides of the copper pad.

2. The method according to claim 1, wherein forming the first oxide film is performed using plasma enhance chemical vapor deposition and forming the second oxide film is performed using an atomic layer deposition method.

3. The method according to claim 1, wherein each of the first oxide film and the second oxide film is made of a material selected from a group consisting of tetra ethyl ortho silicate, SiN and SiC.

4. The method according to claim 1, wherein the first oxide film has a thickness of 1,000 to 3,000 Å.

5. The method according to claim 1, wherein the second oxide film has a thickness of 10 to 20 Å.

6. The method according to claim 1, wherein the second oxide film is formed in a process atmosphere having a pressure of between 100 mTorr to 30 Torr, at a temperature of between 100 to 700° C. and a power of between 200 to 2,000 W.

7. The method according to claim 1, wherein forming the first barrier metal film is performed using a sputtering method and forming the second barrier metal film is performed using an atomic layer deposition (ALD) method.

8. The method according to claim 1, wherein each of the first barrier metal film and the second barrier metal film is made of a material selected from the group consisting of Ti, TiN, Ta, TaN, TiSiN and combinations thereof.

9. The method according to claim 1, wherein the first barrier metal film has a thickness of 500 to 2,000 Å.

10. The method according to claim 1, wherein the second barrier metal film has a thickness of 10 to 20 Å.

11. The method according to claim 1, wherein each of the first barrier metal film and the second barrier metal film is formed in a process atmosphere having a pressure of between 100 mTorr to 50 Torr, at a temperature of between 200 to 800° C. and a power of between 200 to 2,000 W.

12. A method for manufacturing a semiconductor device comprising:
forming first and second semiconductor devices each having an exposed copper pad formed on one side and an exposed substrate on the opposite side; and then
bonding the first and second semiconductor devices; and then
planarizing the exposed substrate of the second semiconductor device exposing a first barrier metal film of the second semiconductor device; and then
forming an insulating film over the substrate of the second semiconductor device and the first barrier film of the second semiconductor device; and then
forming a pad hole in the insulating film exposing the first barrier metal film of the second semiconductor device; and then
sequentially forming second and third barrier metal films in the pad hole; and then
forming a copper layer over the third barrier metal film and in the pad hole; and then
recessing a resultant structure of the substrate of the second semiconductor device at opposite sides of a region including the copper layer and the second and third barrier metal films surrounding the copper layer, thereby exposing the insulating film.

13. The method according to claim 12, wherein forming the second barrier metal film is performed using a sputtering method and forming the third barrier metal film is performed using an atomic layer deposition (ALD) method.

14. The method according to claim 12, wherein each of the second barrier metal film and the third fourth barrier metal film is made of a material selected from the group consisting of Ti, TiN, Ta, TaN, TiSiN and combinations thereof.

15. The method according to claim 12, wherein the second barrier metal film has a thickness of 500 to 2,000 Å.

16. The method according to claim 12, wherein the third barrier metal film has a thickness of 10 to 20 Å.

17. The method according to claim 12, wherein each of the second barrier metal film and the third barrier metal film is formed in a process atmosphere having a pressure of between 100 mTorr to 50 Torr, at a temperature of between 200 to 800° C. and a power of between 200 to 2,000 W.

18. The method according to claim 12, wherein bonding the first and second semiconductor devices comprises bonding a copper pad of the first semiconductor device and a copper pad of the second semiconductor device.

19. The method according to claim 18, wherein bonding the copper pads of the first and second semiconductor devices is performed using a thermal diffusion method.

20. The method of claim 12, wherein forming each of the first and second semiconductor devices comprises:
forming a first insulating film over the substrate; and then
forming first and second metal patterns over the first insulating film; and then
forming a second insulating film over the first insulating film including the first and second metal patterns; and then
forming a trench extending through the first and second insulating films and into the substrate thereby exposing the substrate; and then
sequentially forming first and second oxide films over the second insulating film and in the trench; and then
forming a via hole exposing the first metal pattern; and then
sequentially forming first and second barrier metal films over a resultant surface of the substrate including the second oxide film; and then
forming a copper layer over the second barrier metal film and in the trench and the via hole; and then
planarizing the copper layer exposing a portion of the second barrier metal film; and then
forming a copper pad by recessing predetermined portions of the second barrier metal film, the first barrier metal film, the second oxide film and the first oxide film exposing the second insulating film at opposite sides of the copper pad.
